(19) United States
(12) Patent Application Publication
(10) Pub. No.: US 2026/0349119 A1
(43) Pub. Date: Nov. 5, 2026

(54) RADIATION DETECTOR, DETECTION SYSTEM, AND RADIATION DETECTOR MANUFACTURING METHOD

(71) Applicant: CANON KABUSHIKI KAISHA, Tokyo (JP)

(72) Inventors: ZEMPEI WADA, Saitama (JP); TAKANORI WATANABE, Kanagawa (JP); HAJIME IKEDA, Kanagawa (JP)

(21) Appl. No.: 19/655,253

(22) Filed: Apr. 22, 2026

(30) Foreign Application Priority Data
Apr. 30, 2025 (JP) 2025-075416

(51) Int. Cl. G01T 1/20; H10F 39/00; H10F 39/12

(52) U.S. Cl. CPC G01T 1/20184; H10F 39/195; H10F 39/8037

(57) ABSTRACT

A radiation detector includes a semiconductor substrate having a surface, a photodiode configured to convert radiation into at least one electric charge and accumulate at least one signal charge, a transfer transistor configured to transfer the at least one signal charge accumulated by the photodiode, a floating diffusion layer configured to convert the at least one signal charge into a voltage, a reset transistor configured to reset the floating diffusion layer to a predetermined voltage, and an amplification transistor configured to output an electrical signal based on a voltage of the floating diffusion layer. The transfer transistor, the reset transistor, and the amplification transistor each include a gate and a gate insulating film, which is provided between the gate and the surface. The gate insulating film of the transfer transistor is thinner than the gate insulating film of at least one of the reset transistors and the amplification transistor.

### BACKGROUND

### Field of the Technology

The present disclosure relates to a radiation detector, a detection system, and a radiation detector manufacturing method.

### Description of the Related Art

A radiation detector including a photodiode, a floating diffusion layer, and a transfer transistor that transfers electric charges from the photodiode to the floating diffusion layer is known. When radiation such as an X-ray or an electron beam is directly incident on the radiation detector, the radiation detector may deteriorate over time. Degradation of characteristics of the radiation detector is caused as a result of phenomena such as electric charges generated in an insulating film becoming trapped due to the total ionization dose (TID) effect of radiation and an increase in the defect level. In particular, when the function of the transfer transistor deteriorates, the transfer characteristic for transferring signal charges generated in the photodiode to the floating diffusion layer deteriorates, and thus the quality of a signal generated by the radiation detector may deteriorate.

Japanese Patent Laid-Open No. 2014-49671 discusses a semiconductor device formed such that the thickness of at least one of an insulating film of an amplification transistor and an insulating film of a photodiode is smaller than the thickness of an insulating film of a transfer transistor.

However, the semiconductor device described in Japanese Patent Laid-Open No. 2014-49671 does not assume an embodiment in which the radiation detector is irradiated with radiation. Accordingly, in the radiation detector, it has been difficult to reduce degradation in transfer capability due to degradation of characteristics caused by repeated irradiation.

### SUMMARY

The present disclosure is directed to providing a radiation detector capable of reducing the degradation in transfer capability due to irradiation.

An aspect of the present disclosure provides a radiation detector that includes a semiconductor substrate having a surface, a photodiode configured to convert radiation into at least one electric charge and accumulate at least one signal charge, a transfer transistor configured to transfer the at least one signal charge accumulated by the photodiode, a floating diffusion layer configured to convert the at least one signal charge into a voltage, a reset transistor configured to reset the floating diffusion layer to a predetermined voltage, and an amplification transistor configured to output an electrical signal based on a voltage of the floating diffusion layer. The transfer transistor, the reset transistor, and the amplification transistor each include a gate and a gate insulating film, which is provided between the gate and the surface. The gate insulating film of the transfer transistor is thinner than the gate insulating film of at least one of the reset transistor and the amplification transistor.

Features of the present disclosure will become apparent from the following description of embodiments with reference to the attached drawings. The following description of embodiments is described by way of example.

### BRIEF DESCRIPTION OF THE DRAWINGS

FIG. 1 is a circuit diagram illustrating a pixel circuit according to a first embodiment.

FIG. 2A is a plan view illustrating a pixel structure according to the first embodiment.

FIG. 2B is a cross-sectional view illustrating the pixel structure according to the first embodiment.

FIG. 3A is a plan view illustrating a pixel structure according to a second embodiment.

FIG. 3B is a cross-sectional view illustrating the pixel structure according to the second embodiment.

FIG. 4 is a plan view illustrating a pixel structure according to a third embodiment.

FIG. 5 is a plan view illustrating a pixel structure according to a fourth embodiment.

FIG. 6 is a plan view illustrating a pixel structure according to a fifth embodiment.

FIG. 7A is a circuit diagram illustrating a pixel circuit according to a sixth embodiment.

FIG. 7B is a plan view illustrating a pixel structure according to the sixth embodiment.

FIG. 8A is a circuit diagram illustrating a pixel circuit according to a seventh embodiment.

FIG. 8B is a plan view illustrating a pixel structure according to the seventh embodiment.

FIG. 9 is a cross-sectional view illustrating a pixel structure according to an eighth embodiment.

FIGS. 10A, 10B, 10C, and 10D are cross-sectional views each illustrating a radiation detector manufacturing method according to the second embodiment.

FIG. 11 is a diagram illustrating a configuration of a radiation imaging system according to a ninth embodiment.

FIG. 12A is a diagram illustrating a configuration of a detection system according to a tenth embodiment.

FIG. 12B is a diagram illustrating a configuration of a transmission electron microscope according to the tenth embodiment.

### DESCRIPTION OF THE EMBODIMENTS

Hereinafter, embodiments will be described with reference to the drawings. Note that the following embodiments are not intended to limit the disclosure set forth in the claims. Although a plurality of features is described in the embodiments, not all of these features are necessarily essential to the disclosure, and the features may be combined with one another in any suitable manner. In the accompanying drawings, the same or similar components are denoted by the same reference numerals, and redundant description thereof is incorporated by reference, for conciseness.

In the following embodiments, a sensor for image capturing is mainly described as an example of a radiation detector. However, the embodiments are not limited to a sensor for image capturing, and are also applicable to other examples of the radiation detector. For example, the embodiments are applicable to a dosimetry apparatus (e.g., an apparatus for measuring an incident dose). Further, a case is described in which electrons are handled as signal charges and the device is configured with an N-type transistor; however, when holes are handled as signal charges, the device may be configured with a P-type transistor.

Herein, the term radiation refers to radiation including particulate radiation and electromagnetic radiation (electromagnetic waves). Examples of the particulate radiation include electron beams, alpha rays, beta rays, and neutron rays. Examples of electromagnetic radiation include visible light, infrared light, X-rays, and gamma rays.

Herein, terms that indicate specific directions or positions (for example, up, down, right, and left, and other such terms) are used to facilitate understanding of the embodiments described with reference to the drawings, and the technical scope of the present disclosure is not limited by the meanings of those terms.

Herein, a statement that "a member A and a member B are electrically connected" is not limited to a case where the member A and the member B are directly connected to each other. For example, even when another member C is connected between the member A and the member B, it is sufficient that the member A and the member B are electrically connected.

### First Embodiment

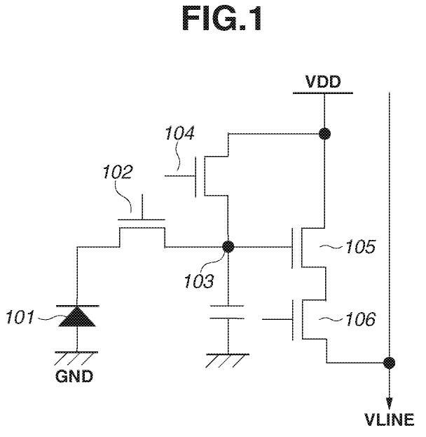

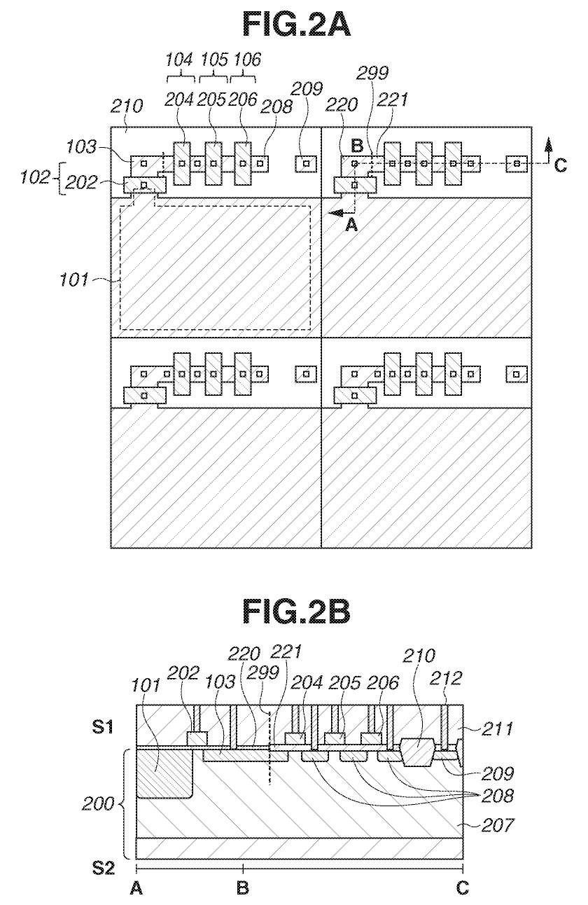

A pixel structure of a radiation detector according to a first embodiment of the present disclosure will be described with reference to FIGS. 1, 2A, and 2B.

FIG. 1 is a circuit diagram illustrating a pixel circuit included in one pixel of the radiation detector according to the first embodiment. A photodiode 101 is a diode formed of a PN junction, and converts incident radiation into signal charges and accumulates the signal charges. Herein, the term photodiode is used to refer to such a device that detects particle radiation such as an electron beam.

A transfer transistor 102 transfers the signal charges accumulated in the photodiode 101 to a floating diffusion layer 103 (hereinafter referred to as FD). The FD 103 converts the signal charges into a voltage, and in subsequent circuits, a signal is handled as a voltage. A reset transistor 104 resets the voltage of the FD 103. An amplification transistor 105 outputs an electrical signal based on an amount of signal charges transferred to the FD 103.

The photodiode 101 and the amplification transistor 105 having properties suitable for an intended use of the radiation detector can be selected. In the radiation detector that detects at least one of an electron beam, a gamma ray, and an X-ray, the photodiode 101 can convert at least one of the electron beam, the gamma ray, and the X-ray into electric charges. The amplification transistor 105 can output an electrical signal based on an amount of radiation of at least one of an electron beam, a gamma ray, and an X-ray.

In an environment in which the radiation detector is exposed to at least one of the electron beam, the gamma ray, and the X-ray, in the radiation detector that detects visible light, the photodiode 101 can convert radiation including the visible light into electric charges. The amplification transistor 105 can output an electrical signal based on an amount of radiation of the radiation including the visible light. Examples of the environment in which the radiation detector is exposed to at least one of the electron beam, the gamma ray, and the X-ray include outer space and a nuclear power plant.

A pixel selection transistor 106 outputs a signal from the amplification transistor 105 to a vertical signal line (VLINE). Although, in the first embodiment, a configuration including the pixel selection transistor 106 is described, a configuration that does not include the pixel selection transistor 106 may also be employed. In such a case, the reset transistor 104 is configured to selectively supply a plurality of voltages to the FD 103. A selected state and a non-selected state of each pixel may be switched in accordance with the level of the voltage of the FD 103.

Although not illustrated in FIG. 1, a signal output via a signal line is output to the outside of the radiation detector via a signal processing circuit or the like in a peripheral circuit region that is located outside a pixel region. Each of the transfer transistor 102, the reset transistor 104, the amplification transistor 105, and the pixel selection transistor 106 may be an N-type Metal-Oxide-Semiconductor (MOS) transistor or a P-type MOS transistor. Some transistors in a pixel may have a conductivity type different from that of other transistors in the pixel.

FIGS. 2A and 2B are a plan view and a cross-sectional view, respectively, illustrating a layout of the pixel circuit of FIG. 1. For convenience of explanation, a state of components from a semiconductor substrate to a contact is illustrated, and components to be formed in processes subsequent to a wiring layer formation process are not illustrated. FIG. 2A is a plan view illustrating a layout of four pixels arranged in two rows and two columns. The radiation detector includes a plurality of pixels arranged in a plurality of rows and a plurality of columns, and FIG. 2A illustrates only four pixels arranged in two rows and two columns extracted therefrom. FIG. 2B is a cross-sectional view taken along a broken line A-B-C in FIG. 2A.

In the cross-sectional view of FIG. 2B, a substrate 200 is a substrate made of a semiconductor such as silicon. A front surface that is a principal surface of the substrate 200 is referred to as S1, and a back surface of the substrate 200 is referred to as S2. In the case of detecting radiation that passes through the substrate 200, the radiation may be incident on either a front surface S1 side or a back surface S2 side of the substrate 200. In the case of detecting an electromagnetic wave that does not transmit through the substrate 200, such as visible light, irradiation may be from the front surface S1 side. However, as long as a signal can be detected even when irradiation is from the back surface S2 side, for example, by reducing the thickness of the substrate 200, irradiation from the back surface S2 side may be employed.

The transfer transistor 102, the reset transistor 104, and the amplification transistor 105 each include a gate and a gate insulating film provided between the gate and the principal surface of the substrate 200.

A well region 207, the photodiode 101, the FD 103, a source and drain region 208 of each transistor, and a diffusion layer 209 of a well contact portion can be formed by implanting dopants into the substrate 200. The transfer transistor 102, the reset transistor 104, the amplification transistor 105, and the pixel selection transistor 106 illustrated in the circuit diagram of FIG. 1 have gates 202, 204, 205, and 206, respectively, which are illustrated in FIGS. 2A and 2B.

A device isolation region 210 is a region for electrically isolating devices from each other, and can be formed of a silicon oxide film by a method called Shallow Trench Isolation (STI) or Local Oxidation of Silicon (LOCOS). Regions other than the device isolation region 210 are referred to as active regions and serve as regions in which a photodiode, a transistor, and the like are formed. The device isolation region 210 is not limited to a configuration using such a silicon oxide film, and instead may have a structure provided with a semiconductor region that contains, as majority carriers, electric charges having a polarity opposite to that of electric charges used as signals.

A gate insulating film 220 is a gate insulating film of the transfer gate 202 included in the transfer transistor 102, and is formed on the front surface S1 of the substrate 200. Because the planarity of the insulating film can be improved by forming the insulating film over a wider area, the gate insulating film 220 may be formed also over the photodiode 101 and the FD 103. A gate insulating film 221 is a gate insulating film of each transistor other than the transfer transistor 102 and is formed on the front surface S1 of the substrate 200.

In the first embodiment, the film thickness of the gate insulating film 220 is smaller than the film thickness of the gate insulating film 221. A step 299 of the gate insulating film is a difference in film thickness at a boundary portion between the gate insulating film 220 and the gate insulating film 221. In the first embodiment, the step 299 of the gate insulating film is formed in an active region between the transfer gate 202 and the reset gate 204 included in the reset transistor 104. An interlayer insulating film 211 is an insulating film formed above the substrate 200, the gate insulating films 220 and 221, and the device isolation region 210.

A contact plug 212 is metal wiring formed to electrically connect a diffusion layer in the substrate 200 and/or the gate to upper wiring.

Prior to mentioning the film thickness relationship between the gate insulating film 220 and the gate insulating film 221, an issue solved by the present disclosure will be described. As known from the TID effect, when a radiation detector is irradiated with radiation such as an X-ray, a gamma ray, a proton beam, or an electron beam, electric charges generated by the ionization action are charged in the insulating film in the radiation detector. This leads to degradation in characteristics of various elements included in the radiation detector.

One example of the degradation of the characteristics in the radiation detector including a MOS transistor (e.g., a complementary metal-oxide semiconductor (CMOS) sensor) is degradation in the transfer capability of the transfer transistor. The degradation in the transfer capability refers to a decrease in an amount of signal charges, which are detected by the photodiode, transferred to the FD per unit time, or a decrease in a maximum value of the amount of signal charges that can be transferred from the photodiode to the FD. Factors that cause the degradation in the transfer capability include an increase in an amount of electric charges becoming trapped or an increase in defects in the gate insulating film located below the transfer gate 202 due to the irradiation. Due to at least one of these factors, the degradation in the transfer capability of the transfer transistor occurs.

The degradation in the transfer capability makes it difficult to accurately detect radiation or an electromagnetic wave such as visible light to be detected, which leads to degradation in quality of an output signal from the radiation detector. The degradation in the quality of the output signal from the radiation detector leads to degradation in quality of an image to be generated using the output signal. This issue may occur due to the radiation detector being used in an environment in which the radiation detector is exposed to radiation even in a case where an electromagnetic wave such as visible light is to be detected. Therefore, various applications can be contemplated as application examples of the radiation detector according to the present disclosure, including an industrial inspection apparatus that detects gamma rays or X-rays, an electron microscope that detects an electron beam, and a visible-light camera and an infrared camera that are used in outer space or a nuclear power plant.

The confirmed degradation in the transfer capability can be reduced by reducing the thickness of the gate insulating film to reduce an influence due to charging of electric charges and an increase in defects. On the other hand, when the thickness of the gate insulating film of a transistor is reduced, a withstand voltage of the transistor decreases. Accordingly, the voltage applied to the transistor is to be reduced. In particular, when the thickness of the gate insulating film of the reset transistor is reduced, a reset voltage of the FD is to be reduced. As a result, a voltage operation range of the pixel circuit becomes narrow, and an effective voltage range of a signal output from the pixel becomes narrow. This leads to a decrease in a dynamic range of an image to be generated using an output signal from the radiation detector.

Thus, the thickness of only the gate insulating film 220 of the transfer transistor 102 may be reduced without reducing the thickness of the gate insulating film 221 of the transistors other than the transfer transistor 102. In other words, the film thickness of the gate insulating film of the transfer transistor 102 may be smaller than the film thickness of the gate insulating film of at least one of the reset transistor 104 and the amplification transistor 105. This makes it possible to reduce the degradation in the transfer capability of the transfer transistor 102 while maintaining the voltage operation range of the pixel circuit. From a viewpoint of reducing the decrease in the dynamic range, the film thickness of the gate insulating film of the transfer transistor 102 may be smaller than the film thickness of the gate insulating film of the reset transistor 104.

From a viewpoint of reducing the degradation in the transfer capability of the transfer transistor 102, the gate insulating film of the transfer transistor 102 may have a film thickness of 15 Å or more and 80 Å or less. The lower limit value of the gate insulating film can be changed in accordance with durability for the radiation detector.

As one example, to drive each pixel circuit at 3.3 V, the film thickness of the gate insulating film 221 of the transistors other than the transfer transistor 102 may be set to about 80 Å. The thickness of the gate insulating film 220 of the transfer gate 202 may be reduced to 75 Å or less (a film thickness that is thinner by 5 Å or more than the film thickness of the gate insulating film 221). Although further reduction in thickness may reduce the degradation of characteristics caused by radiation, the film thickness may be determined in consideration of a withstand-voltage design of the transfer gate 202, a device design of the photodiode 101, and durability for the radiation detector.

In the first embodiment, the configuration in which the thickness of the gate insulating film of the transfer gate 202 among the plurality of gates is reduced is described. However, the configuration of the radiation detector according to the present disclosure is not so limited. Depending on a pixel layout or product specifications, the film thickness of the gate insulating film may be reduced for a combination such as a combination of the transfer gate 202 and the reset gate 204, or a combination of the transfer gate 202 and the amplification gate 205, which is included in the amplification transistor 105. In other words, the film thickness of the gate insulating film of the transfer gate 202 may be formed to be smaller than the film thickness of the gate insulating film of at least some of the other transistors in the pixel.

### Second Embodiment

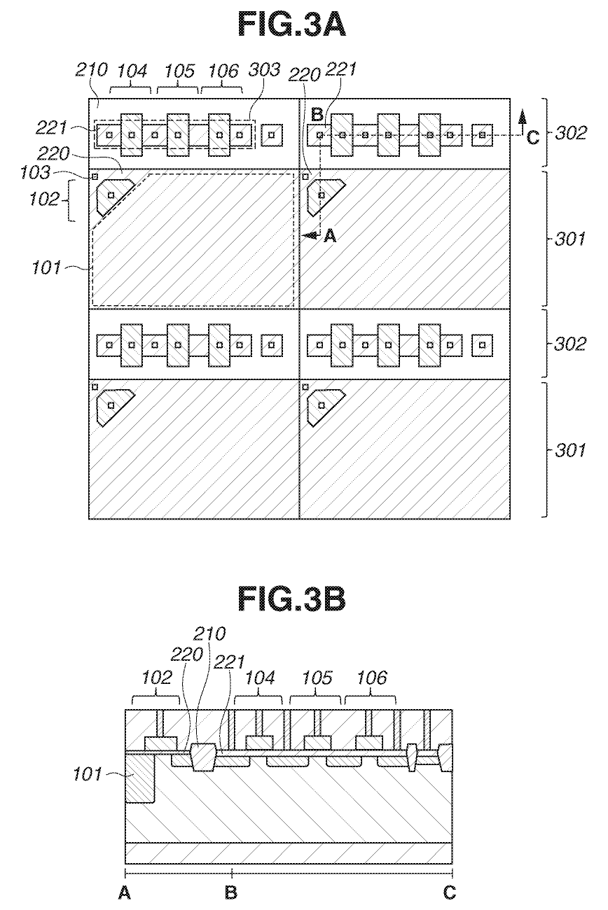

A pixel structure of a radiation detector according to a second embodiment of the present disclosure will be described with reference to FIGS. 3A and 3B. A pixel according to the second embodiment has a structure in which an active region 301 in which the transfer transistor 102 is provided and an active region 303 in which the reset transistor 104 is provided are isolated from each other by a device isolation region formed of an insulating material.

FIG. 3A is a plan view illustrating a pixel structure according to the second embodiment, and illustrates a range of four pixels arranged in two rows and two columns. FIG. 3B is a cross-sectional view taken along a broken line A-B-C in FIG. 3A.

In the active region 301, the photodiode 101, the transfer transistor 102, and the FD 103 are formed. In a region 302, the transistors 104, 105, and 106, which are transistors other than the transfer transistor 102, and the well contact portion are arranged. The gate insulating film 220 formed in the active region 301 has a thickness that is relatively smaller than the thickness of the gate insulating film 221 formed in the region 302.

Differences between the second embodiment and the first embodiment will be described. In a case where the step 299 of the gate insulating film described above with reference to FIGS. 2A and 2B is present, because the shape of the gate insulating film becomes complicated, it becomes difficult to ensure the planarity. Further, fine etching control leads to an increase in manufacturing cost.

In contrast, in the second embodiment, the active region 301 in which the transfer transistor 102 is provided and the active region 303 in which the reset transistor 104 is provided are isolated from each other by the device isolation region 210, which is an insulator. When the device isolation region 210 is a silicon oxide film and the insulating film 220 and the insulating film 221 are formed by a thermal oxidation process described below, the step 299 of the gate insulating film is not formed on the FD 103. In other words, the configuration according to the second embodiment makes it possible to ensure the planarity of the gate insulating film described above and to reduce manufacturing cost.

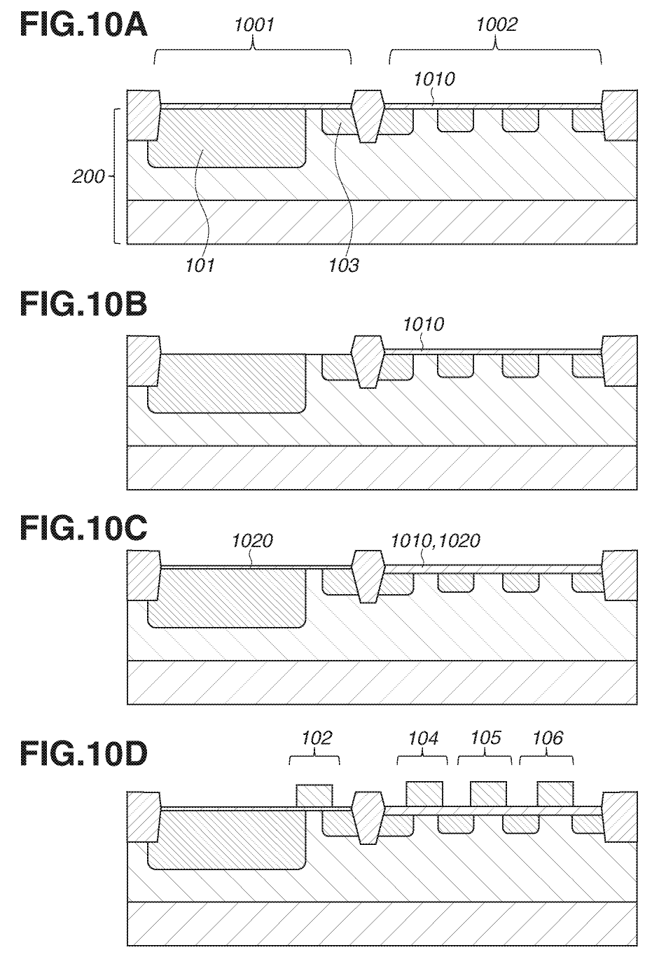

Processes for forming the gate insulating film according to the second embodiment will be described with reference to FIGS. 10A-10D. FIGS. 10A-10D are cross-sectional views each illustrating a pixel structure in the processes for forming the gate insulating film. The gate insulating film according to the second embodiment may be formed by performing the thermal oxidation process twice.

FIG. 10A illustrates a state where the photodiode 101 is preliminarily formed in the substrate 200 and an insulating film 1010 is formed by a first thermal oxidation process on the principal surface of the substrate 200 provided with STI. The insulating film 1010 is formed in both a transfer transistor region 1001 and a transistor region 1002 for transistors other than the transfer transistor 102.

Herein, the transfer transistor region 1001 refers to an active region for providing the transfer transistor 102, and the transistor region 1002 for transistors other than the transfer transistor 102 refers to an active region for providing the reset transistor 104 and the amplification transistor 105.

FIG. 10B illustrates a state where at least a part of the insulating film 1010 provided in the transfer transistor region 1001 is selectively removed by wet etching between the first thermal oxidation process and a second thermal oxidation process.

FIG. 10C illustrates a state where an insulating film 1020 is formed on the front surface of the substrate 200 by the second thermal oxidation process. When the insulating film 1010 is entirely removed, the film thickness of the gate insulating film in the transfer transistor region 1001 is substantially the same as the film thickness of the insulating film 1020 formed by the second thermal oxidation process. In contrast, the film thickness of the gate insulating film in the transistor region 1002 for transistors other than the transfer transistor 102 is substantially the same as a sum of the film thickness of the insulating film 1010 formed in the first thermal oxidation process and the film thickness of the insulating film 1020 formed in the second thermal oxidation process. Note that "substantially the same film thickness" is not limited to a strictly equal film thickness, and includes manufacturing tolerances; for example, a difference of about ±10% may be allowed.

FIG. 10D illustrates a state where the gate of each transistor is formed on the gate insulating film after the second thermal oxidation process.

By the manufacturing method illustrated in FIGS. 10A-10D, as described above, the film thickness of the gate insulating film formed in the transfer transistor region 1001 can be formed to be smaller than the film thickness of the gate insulating film formed in the transistor region 1002 for transistors other than the transfer transistor 102. This manufacturing method, however, is merely an example, and the manufacturing method is not to be limited thereto.

### Third Embodiment

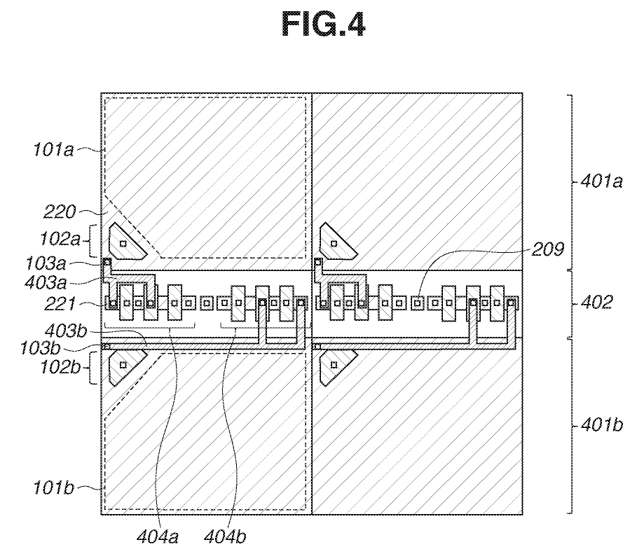

A pixel structure of a radiation detector according to a third embodiment of the present disclosure will be described with reference to FIG. 4.

In the radiation detector according to the third embodiment, a first region and a second region that include gate insulating films with different film thicknesses are formed on the principal surface of the semiconductor substrate 200. In the first region, the photodiode 101 and the gate of the transfer transistor 102 are provided, and in the second region, the reset transistor 104 and the amplification transistor 105 of a plurality of pixels are provided. The film thickness of the gate insulating film of the transfer transistor 102 provided in the first region is smaller than the film thickness of the gate insulating film of at least one of the reset transistor 104 and the amplification transistor 105 provided in the second region. A first pixel and a second pixel that are adjacent to each other each include the first region, and the second region extends over the first pixel and the second pixel and is provided between the first region of the first pixel and the first region of the second pixel.

FIG. 4 is a plan view illustrating a pixel structure according to the third embodiment, and illustrates a range of four pixels arranged in two rows and two columns. In the pixels arranged in two rows and two columns, one first region among a plurality of first regions extends over the pixel located in the first row and the first column and the pixel located in the first row and the second column. Another first region among the plurality of first regions extends over the pixel located in the second row and the first column and the pixel located in the second row and the second column, and the second region is provided between the one first region and the other first region.

In the embodiments described above, the pixels having the same layout are arranged in a plurality of rows and a plurality of columns. In the third embodiment, however, a plurality of pixels having different layouts is arranged in the plurality of rows and the plurality of columns, and portions of the adjacent pixels are formed to be vertically symmetric. In the drawings, a reference numeral of an upper pixel is suffixed with "a", and a reference numeral of a lower pixel is suffixed with "b".

In a region 401a, a photodiode 101a, a transfer transistor 102a, and an FD 103a of an upper pixel are arranged. In a region 401b, a photodiode 101b, a transfer transistor 102b, and an FD 103b of a lower pixel are arranged. Layouts of the region 401a and the region 401b may be configured to be vertically inverted with respect to each other in the drawing. Wiring 403a is metal wiring connected to the FD 103a of the upper pixel, and wiring 403b is metal wiring connected to the FD 103b of the lower pixel. Illustration of other wiring is not included, for clarity.

A region 402 is a region sandwiched between the region 401a and the region 401b. Transistors (e.g., the reset transistor 104, the amplification transistor 105, and the pixel selection transistor 106) other than the transfer transistor 102 of the upper and lower pixels are arranged in the region 402. A transistor region 404a is a transistor region of the upper pixel, and a transistor region 404b is a transistor region of the lower pixel. The thickness of the gate insulating film formed in the region 401a and the region 401b including the transfer transistor 102 is to be smaller than the thickness of the gate insulating film formed in the region 402.

Differences between the third embodiment and the second embodiment will be described. In FIGS. 3A and 3B according to the second embodiment, the region 302 is required for each pixel. However, in FIG. 4 according to the third embodiment, it is sufficient that one region 402 is provided for two pixels when viewed in the vertical direction. An efficient layout with reduced redundant space can be implemented by arranging transistors other than the transfer transistor 102 of each of the upper and lower pixels within the region 402. One well contact 209 can be shared by the upper and lower pixels. With these effects, for example, it becomes possible to manufacture smaller pixels while suppressing an area of the photodiode 101 from being reduced, so that an image with a higher resolution can be obtained.

### Fourth Embodiment

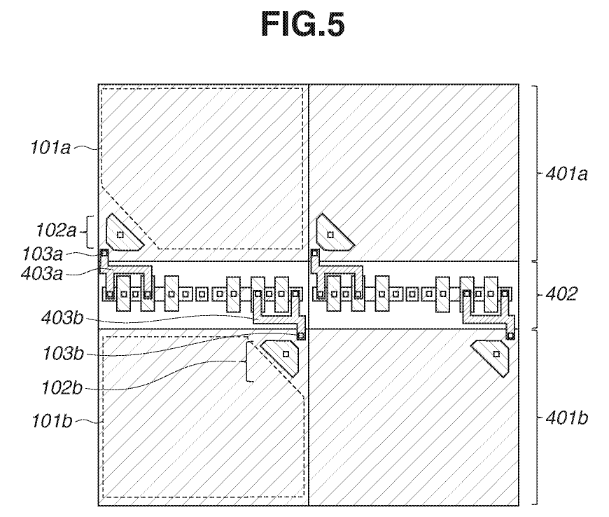

A pixel structure of a radiation detector according to a fourth embodiment of the present disclosure will be described with reference to FIG. 5.

As in the third embodiment, the first region and the second region that include gate insulating films with different film thicknesses are formed on the principal surface of the semiconductor substrate 200. In the first region, the photodiode 101 and the gate of the transfer transistor 102 are provided, and in the second region, the reset transistor 104 and the amplification transistor 105 of the plurality of pixels are provided. The film thickness of the gate insulating film of the transfer transistor 102 provided in the first region is smaller than the film thickness of the gate insulating film of at least one of the reset transistor 104 and the amplification transistor 105 provided in the second region. The first pixel and the second pixel that are adjacent to each other each include the first region, and the second region extends over the first pixel and the second pixel and is provided between the first region of the first pixel and the first region of the second pixel.

In the fourth embodiment, unlike in the third embodiment, portions of layouts of adjacent pixels are formed to be rotationally symmetric such that a wiring length from the FD 103 to the gate of the amplification transistor 105 is substantially the same between the adjacent pixels.

FIG. 5 is a plan view illustrating a pixel structure according to the fourth embodiment. In FIG. 4, the relationship between the region 401a and the region 401b is set to be vertically inverted. However, the layout of the wiring 403a cannot be made identical to the layout of the wiring 403b due to the arrangement of the transistors. In contrast, in FIG. 5, the relationship between the region 401a and the region 401b is set to be rotationally symmetric by 180-degree rotation. With this structure, the wiring 403a and the wiring 403b can have the same shape, so that wiring capacitances of the FDs of the upper and lower pixels can be made substantially the same. Accordingly, differences in the characteristics between the upper pixel and the lower pixel can be reduced, thereby improving image quality of a captured image.

Although the symmetry of the layout is mentioned in the fourth embodiment, the symmetry is not strictly required.

### Fifth Embodiment

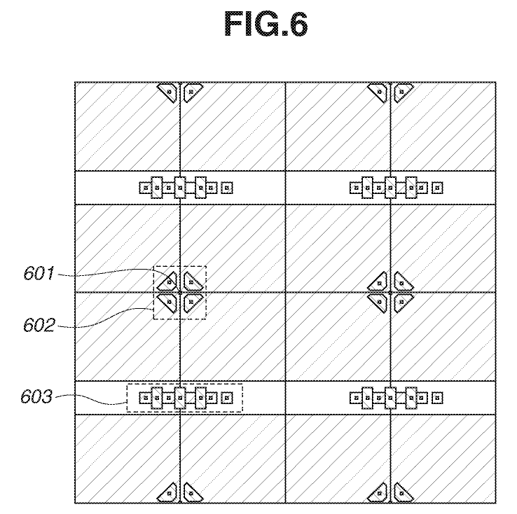

A pixel structure of a radiation detector according to a fifth embodiment of the present disclosure will be described with reference to FIG. 6. In the fifth embodiment, one FD is shared by a plurality of adjacent pixels.

FIG. 6 is a plan view illustrating a pixel structure according to the fifth embodiment, and illustrates a range of 4 × 4 pixels. In the fifth embodiment, one FD 601 is shared by four pixels arranged in two rows and two columns. In this layout, transfer transistors 102 of four pixels are arranged in a region 602. By forming the transfer transistor 102 of each pixel within such a limited region, the transfer transistor 102 is less susceptible to an influence of thickness non-uniformity of the gate insulating film. This makes it possible to reduce characteristic variations among pixels.

When one FD 601 is shared by four pixels, it is sufficient to provide a set of pixel circuits subsequent to the transfer transistor 102 (i.e., the reset transistor 104, the amplification transistor 105, and the pixel selection transistor 106) for every four pixels, thereby reducing the number of transistors. As a result, a failure rate can be reduced.

Although, in the fifth embodiment, an example where one FD 601 is shared by four pixels is described, the number of pixels that share one FD 601 is not limited to four. A similar effect can be obtained when two pixels or eight or more pixels are used.

### Sixth Embodiment

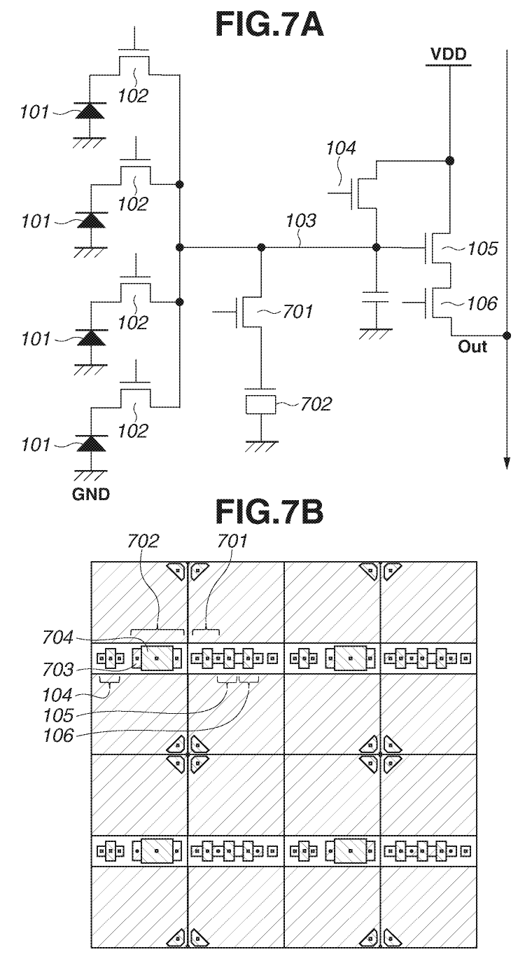

A pixel structure of a radiation detector according to a sixth embodiment of the present disclosure will be described with reference to FIGS. 7A and 7B. In the sixth embodiment, a layout having a function of switching capacitance of the FD 103 is provided.

FIG. 7B is a plan view illustrating a pixel structure according to the sixth embodiment, and illustrates a range of 4 × 4 pixels. A gate capacitor 702 for adding an FD capacitance and a capacitance change transistor 701 serving as a switch for changing the FD capacitance by changing a connection state between the gate capacitor 702 and the FD 103 are added to the configuration illustrated in FIG. 6. As in a transistor, the gate capacitor 702 includes a gate insulating film 703 and a gate 704.

This configuration makes it possible to change a capacitance value of the FD 103 in accordance with the potential at the gate of the capacitance change transistor 701. Typically, the capacitance value of the FD 103 can be switched by turning the capacitance change transistor 701 on and off; however, the configuration is not limited to this form. Specifically, three or more potential values may be set for the gate of the capacitance change transistor 701, and the capacitance value of the FD 103 may be changed to three or more values. With this configuration, both improvement in sensitivity of each pixel and expansion of the dynamic range of a captured image can be achieved. In addition, as with the gate insulating film of the transfer transistor 102, the thickness of the gate insulating film 703 can be reduced. Accordingly, since the gate capacitance can be increased, the dynamic range is expanded.

### Seventh Embodiment

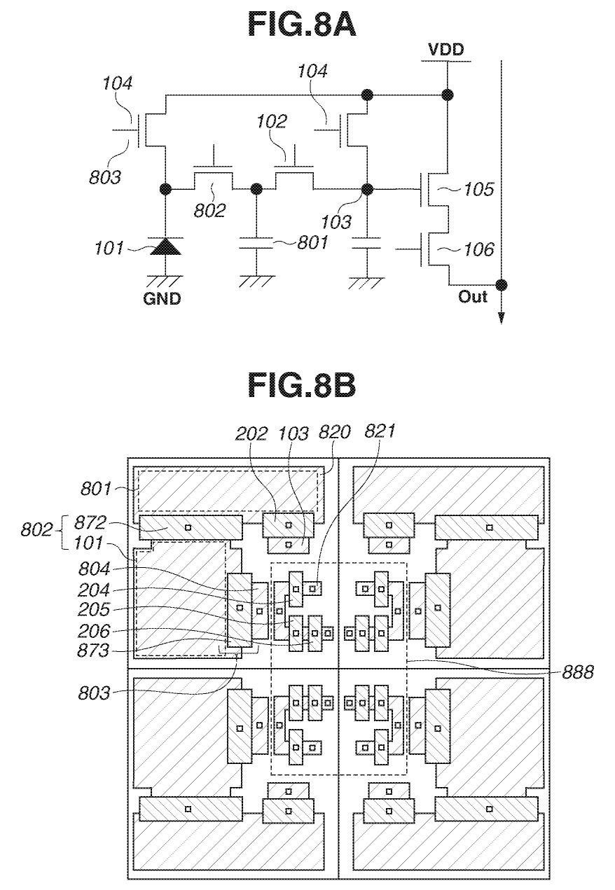

A pixel structure of a radiation detector according to a seventh embodiment of the present disclosure will be described with reference to FIGS. 8A and 8B. In the seventh embodiment, a radiation detector having a global shutter function is provided.

FIGS. 8A and 8B relate to the seventh embodiment. FIG. 8A is a pixel circuit diagram. FIG. 8B is a plan view illustrating a range of four pixels arranged in two rows and two columns. A configuration of a pixel circuit illustrated in FIG. 8A will be described. A memory portion 801 and a memory transfer transistor 802 that are located between the photodiode 101 and the transfer transistor 102 are added to the configuration of the first embodiment illustrated in FIG. 1. The memory portion 801 is a capacitor capable of holding signal charges generated by the photodiode 101 for a predetermined period of time. The memory transfer transistor 802 is a transistor for transferring the signal charges generated by the photodiode 101 to the memory portion 801.

An overflow drain (OFD) transistor 803 is provided for discharging the signal charges generated by the photodiode 101. Such a configuration enables a global shutter operation in which signal charges are simultaneously transferred from the photodiode 101 to the memory portion 801 to be performed in all pixel rows. A generally known method may be employed for a circuit operation sequence, and thus a description thereof is incorporated by reference, for clarity.

The plan view of FIG. 8B will be described. The memory portion 801 is a region that holds the above-described signal charges and is formed in the semiconductor substrate 200. A gate 872 of the memory transfer transistor 802 is disposed between the photodiode 101 and the memory portion 801, and a gate 873 of the OFD transistor 803 is disposed between the photodiode 101 and a power supply 804 (VDD).

A relationship between film thicknesses of gate insulating films of the transistors illustrated in FIGS. 8A and 8B will be described. The gate insulating film of each of the transfer transistor 102, the memory transfer transistor 802, and the OFD transistor 803 is formed with a thickness that is relatively smaller than the thickness of the gate insulating film of the other transistors (the reset transistor 104, the amplification transistor 105, and the pixel selection transistor 106). The gate insulating film of each of the transfer transistor 102, the memory transfer transistor 802, and the OFD transistor 803 may be formed only in a region below the corresponding gate. As illustrated in FIG. 8B, the gate insulating film may be formed to extend to the active region including the photodiode 101, the memory portion 801, and the FD 103.

Effects of the seventh embodiment will be described. The memory transfer transistor 802 also has a function of transferring signal charges. Accordingly, as with the transfer transistor 102, the thickness of the gate insulating film of the memory transfer transistor 802 can be reduced to thereby reduce degradation of both transistors due to irradiation. Although, in FIG. 8B, the thickness of the gate insulating film of the OFD transistor 803 is also reduced, this is not limiting.

In the layout having the global shutter function, from a viewpoint of improving the planarity of the gate insulating film, regions where the transistors other than the transfer transistor 102 are provided can be gathered as indicated by a region 888 illustrated in FIG. 8B.

In other words, the first region and the second region that include gate insulating films with different film thicknesses are formed on the principal surface of the semiconductor substrate 200. As illustrated in FIGS. 8A and 8B, in the radiation detector including the first pixel, the second pixel, a third pixel, and a fourth pixel, the first pixel and the second pixel are adjacent to each other in a first direction in a planar view, and the third pixel and the fourth pixel are adjacent to each other in the first direction in the planar view. The first pixel and the third pixel are adjacent to each other in a second direction, which is different from the first direction, in the planar view. The second pixel and the fourth pixel are adjacent to each other in the second direction in the planar view. The first pixel, the second pixel, the third pixel, and the fourth pixel each include the photodiode 101 and the transfer transistor 102. The photodiode 101 and the gate of the transfer transistor 102 are provided in the first region, and the reset transistor 104 and the amplification transistor 105 of the plurality of pixels are provided in the second region. The film thickness of the gate insulating film of the transfer transistor 102 provided in the first region is smaller than the film thickness of the gate insulating film of at least one of the reset transistor 104 and the amplification transistor 105 provided in the second region.

### Eighth Embodiment

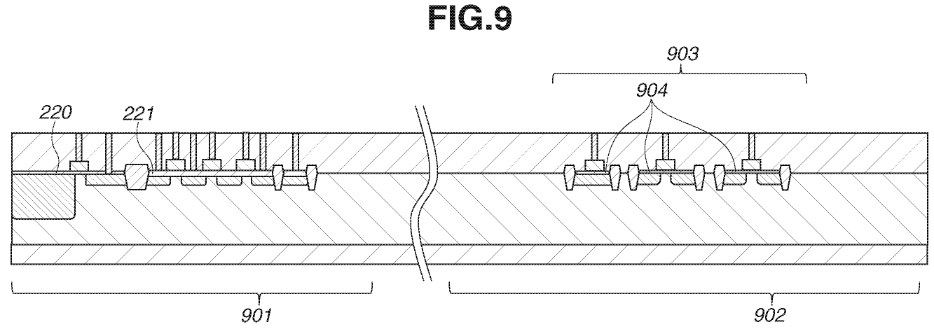

A pixel structure of a radiation detector according to an eighth embodiment of the present disclosure will be described with reference to FIG. 9. The radiation detector according to the eighth embodiment includes a signal processing circuit for outputting signals generated by pixels to the outside, or a drive circuit for driving the pixels and the signal processing circuit. The signal processing circuit and the drive circuit are referred to as peripheral circuits.

FIG. 9 relates to the eighth embodiment, and is a cross-sectional view of the radiation detector including a pixel region 901 and a peripheral circuit region 902. A region 903 is a transistor region in a part of the peripheral circuit region 902. For example, a logic circuit that operates with a lower voltage than that for an analog circuit can be provided in the region 903.

A gate insulating film 904 is a gate insulating film in the transistor region 903. The film thickness of the gate insulating film 220 of the transfer transistor 102 in the pixel region 901 is substantially the same as the film thickness of the gate insulating film 904 in the transistor region 903 in a part of the peripheral circuit region 902. This configuration makes it possible to form the gate insulating film 220 of the transfer transistor 102 in the pixel region 901 simultaneously with formation of the peripheral circuit region 902, thereby enabling simplification of manufacturing processes. Note that "substantially the same film thickness" is not limited to a "strictly equal film thickness", and manufacturing tolerance of about ±10% may be allowed.

### Ninth Embodiment

In the descriptions above, examples of configurations of the radiation detector are described as the embodiments. In a ninth embodiment, a radiation imaging system is described as an example of a detection system including any one of the above-described radiation detectors.

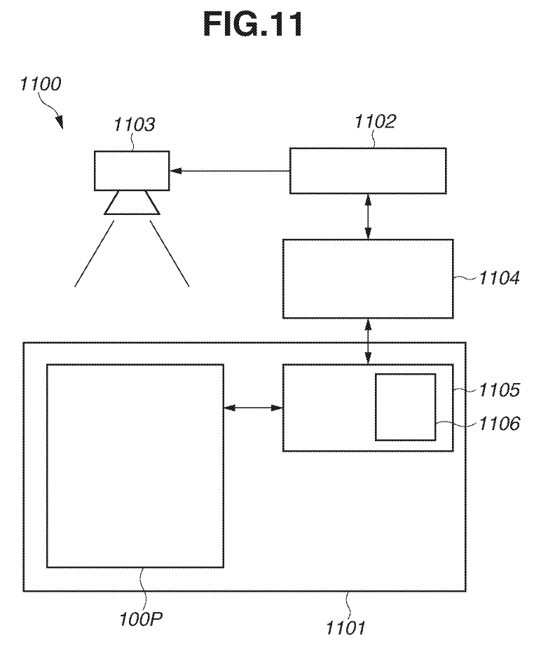

A radiation imaging system 1100 illustrated in FIG. 11 is a detection system including an imaging unit 1101 as the radiation detector, an exposure control unit 1102, a radiation source 1103 as a radiation emission unit, and a computer 1104. The imaging unit 1101 includes an imaging panel 100P including a pixel array. The imaging panel 100P may be any one of the radiation detectors described in the first to eighth embodiments, or a modified example thereof.

The radiation source 1103 starts emission of radiation in accordance with an exposure command from the exposure control unit 1102. Radiation emitted from the radiation source 1103 passes through an imaging target (subject) and is incident on the imaging panel 100P of the imaging unit 1101. The radiation source 1103 stops emission of radiation in accordance with a stop command from the exposure control unit 1102.

The imaging unit 1101 is, for example, a flat panel detector used for radiography in medical diagnostic imaging, non-destructive inspection, and the like. The imaging panel 100P of the imaging unit 1101 can be formed in a plate shape having a size that matches a size of an imaging target. For example, the imaging panel 100P may have 3300 × 2800 pixels arranged on a substrate having a size of 550mm × 445mm. The imaging unit 1101 may have a direct conversion configuration in which a detection diode provided in the pixel array of the imaging panel 100P converts radiation into signal charges.

The imaging unit 1101 includes the above-described imaging panel 100P, a control unit 1105 for controlling the imaging panel 100P, and a signal processing unit 1106 for processing a signal output from the imaging panel 100P. The signal processing unit 1106 may, for example, perform an analog-to-digital (A/D) conversion on the signal output from the imaging panel 100P and output the converted signal to the computer 1104 as digital image data. The signal processing unit 1106 may generate a stop signal for stopping emission of radiation from the radiation source 1103, for example, based on the signal output from the imaging panel 100P. The stop signal is supplied to the exposure control unit 1102 via the computer 1104. The exposure control unit 1102 sends the stop command to the radiation source 1103 in response to the stop signal.

The control unit 1105 may be configured by, for example, a programmable logic device (PLD) such as a field programmable gate array (FPGA). As another example, the control unit 1105 may be configured by an application specific integrated circuit (ASIC) or a general-purpose computer in which a program is incorporated. The control unit 1105 may be configured by all or part of these.

In the present embodiment, the signal processing unit 1106 is illustrated as being disposed in the control unit 1105 or as being a part of functions of the control unit 1105; however, the configuration thereof is not limited thereto. The control unit 1105 and the signal processing unit 1106 may have separate configurations. The signal processing unit 1106 may be provided separately from the imaging unit 1101. For example, the computer 1104 may have the function of the signal processing unit 1106. Accordingly, the signal processing unit 1106 may be included in the radiation imaging system 1100 as a signal processing device that processes signals output from the imaging unit 1101.

The computer 1104 can control the imaging unit 1101 and the exposure control unit 1102, receive radiation image data from the imaging unit 1101, and perform processing for displaying the data as a radiation image. The computer 1104 can function as an input unit for a user to input conditions for capturing a radiation image.

For example, the exposure control unit 1102 includes an exposure switch. When the exposure switch is turned on by the user, the exposure control unit 1102 sends an exposure command to the radiation source 1103, and also sends a start notification indicating a start of emission of radiation to the computer 1104. The computer 1104 that has received the start notification notifies the control unit 1105 of the imaging unit 1101 of the start of emission of radiation in response to the start notification. In response thereto, the control unit 1105 generates a signal in accordance with incident radiation on the imaging panel 100P.

### Tenth Embodiment

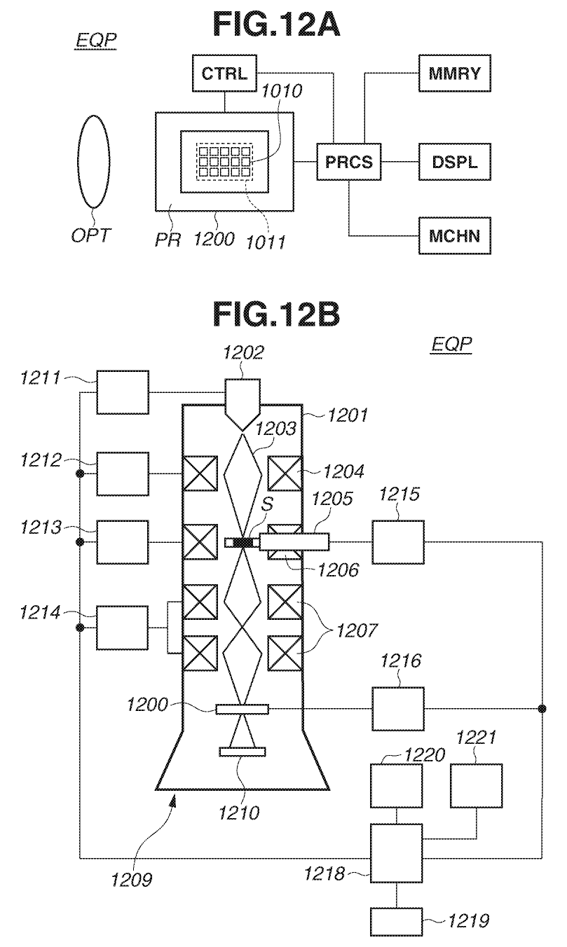

In a tenth embodiment, another example of the detection system including any one of the radiation detectors according to the first to eighth embodiments will be described. FIG. 12A illustrates equipment EQP as the detection system including any one of the radiation detectors according to the first to eighth embodiments or a radiation detector 1200 as a modified example thereof.

The radiation detector 1200 includes a pixel array 1011 in which pixels 1010 are arranged in a matrix, and a peripheral region PR surrounding the pixel array 1011. Peripheral circuits (e.g., a vertical scanning circuit and a column circuit portion) may be provided in the peripheral region PR.

The equipment EQP can include at least one of an optical system OPT, a control device CTRL, a processing device PRCS, a display device DSPL, a memory device MMRY, and a mechanical device MCHN. The optical system OPT forms an image of radiation on the radiation detector 1200, and is, for example, a lens, a shutter, or a mirror. The optical system OPT may form an image of a particle beam such as an electron beam or a proton beam on the radiation detector 1200 depending on a type of radiation to be handled. The control device CTRL controls the radiation detector 1200 and is, for example, an ASIC. The processing device PRCS processes a signal output from the radiation detector 1200, and is a device such as a central processing unit (CPU) or an ASIC for configuring an analog front end (AFE) or a digital front end (DFE).

The display device DSPL is an electroluminescent (EL) display device or a liquid crystal display device for displaying information obtained by the radiation detector 1200 in a form of a visible image or the like. The memory device MMRY is a magnetic device or a semiconductor device that stores information obtained by the radiation detector 1200. The memory device MMRY is a volatile memory such as a static random access memory (SRAM) or a dynamic random access memory (DRAM), or a nonvolatile memory such as a flash memory or a hard disk drive. The mechanical device MCHN includes a movable portion or a propulsion portion such as a motor or an engine.

The equipment EQP displays a signal output from the radiation detector 1200 on the display device DSPL, or transmits the signal to the outside by a communication device included in the equipment EQP. For this purpose, the equipment EQP can include the memory device MMRY and the processing device PRCS separately from a storage circuit and an arithmetic circuit included in the radiation detector 1200. The mechanical device MCHN may be controlled based on the signal output from the radiation detector 1200.

The equipment EQP illustrated in FIG. 12A may be a medical device such as an endoscope or a radiation diagnostic apparatus, a measurement device such as a distance measurement sensor, or an analysis device such as an electron microscope.

FIG. 12B is a schematic diagram illustrating a configuration of a transmission electron microscope (TEM) as an example of the equipment EQP. The equipment EQP as an electron microscope includes an electron beam source 1202 as a radiation (electron beam) irradiation unit, an irradiation lens 1204, a vacuum chamber 1201 (lens barrel), an objective lens 1206, and a magnifying lens system 1207. The equipment EQP also includes a camera 1209 as an imaging unit. The camera 1209 includes the direct detection radiation detector 1200.

An electron beam 1203 that is radiation emitted from the electron beam source 1202 is focused by the irradiation lens 1204, and is emitted to a sample S as an analysis target held in a sample holder. A space through which the electron beam 1203 passes is formed by the vacuum chamber 1201 (lens barrel), and this space is kept in a vacuum state. The radiation detector 1200 is disposed to face a vacuum space through which the electron beam 1203 passes. The electron beam 1203 transmitted through the sample S is magnified by the objective lens 1206 and the magnifying lens system 1207, and is projected onto the radiation detector 1200. An electron optical system for irradiating the sample S with the electron beam 1203 is referred to as an irradiation optical system, and an electron optical system for forming an image of the electron beam 1203 transmitted through the sample S on the radiation detector 1200 is referred to as an imaging optical system.

The electron beam source 1202 is controlled by an electron beam source control device 1211. The irradiation lens 1204 is controlled by an irradiation lens control device 1212. The objective lens 1206 is controlled by an objective lens control device 1213. The magnifying lens system 1207 is controlled by a magnifying lens system control device 1214. A control mechanism 1205 of the sample holder is controlled by a holder control device 1215 that controls a drive mechanism of the sample holder.

The electron beam 1203 that has transmitted through the sample S is detected by the radiation detector 1200 of the camera 1209. An output signal from the radiation detector 1200 is processed by a signal processing device 1216 and an image processing device 1218 each serving as the processing device PRCS, and an image signal is generated. The generated image signal (transmitted electron image) is displayed on an image display monitor 1220 and an analysis monitor 1221 each corresponding to the display device DSPL.

The camera 1209 is provided in a lower portion of the equipment EQP. The camera 1209 includes the radiation detector 1200 that directly converts an electron beam into an electric charge signal. The radiation detector 1200 corresponds to an image sensor. At least some components of the camera 1209 are provided in the camera 1209 so as to be exposed to the vacuum space formed by the vacuum chamber 1201. The electron beam 1203 transmitted through the radiation detector 1200 is absorbed by an electron-beam absorbing member 1210. The camera 1209 may be configured to be detachably attached to the vacuum chamber 1201. When it becomes necessary to replace the radiation detector 1200, the camera 1209 can be detached from the vacuum chamber 1201 so that the camera 1209 can be replaced with a new one. To replace the camera 1209 without breaking the vacuum state of the vacuum chamber 1201, a vacuum partition wall that can be opened and closed may be provided between the camera 1209 and the vacuum chamber 1201.

The electron beam source control device 1211, the irradiation lens control device 1212, the objective lens control device 1213, the magnifying lens system control device 1214, and the holder control device 1215 are each connected to the image processing device 1218. This configuration enables mutual data exchange for setting imaging conditions of the electron microscope. In this case, the electron beam source control device 1211 and the image processing device 1218 function as a control unit for controlling an irradiation rate of radiation. Based on a signal output from the image processing device 1218, driving of the sample holder can be controlled and observation conditions of each lens can be set.

An operator prepares the sample S to be an imaging target, and sets imaging conditions using an input device 1219 connected to the image processing device 1218. The operator inputs predetermined data to the electron beam source control device 1211, the irradiation lens control device 1212, the objective lens control device 1213, and the magnifying lens system control device 1214, thereby making it possible to obtain an acceleration voltage, magnification, and observation mode. In addition, the operator also inputs conditions such as the number of continuous field-of-view images, a start position for imaging, and a moving speed of the sample holder to the image processing device 1218 using the input device 1219 such as a mouse, a keyboard, or a touch panel. Instead of using an input by the operator, the image processing device 1218 may be configured to automatically set the conditions.

The detection systems described in the ninth and tenth embodiments above are merely examples. The radiation detectors described in the first to eighth embodiments or a modified radiation detector thereof may be applied to other detection systems.

Herein, expressions such as "A or B," "at least one of A and B," "at least one of A and/or B," and "one or more of A and/or B" include, unless expressly defined otherwise, all possible combinations of the listed items. More specifically, such expressions are understood to disclose all of the following cases: a case including at least one A; a case including at least one B; and a case including both at least one A and at least one B. The same applies to combinations of three or more elements.

The embodiments described above may be modified as appropriate without departing from the technical concept. The present disclosure includes not only matters described herein but also all matters that can be understood from this disclosure and the drawings appended hereto. In addition, the disclosure includes the complements of the concepts described herein. More specifically, when the present disclosure includes, for example, a description to the effect that "A is greater than B," then even if a description to the effect that "A is not greater than B" is not found, it can be said that "A is not greater than B." This is because, where a description to the effect that "A is greater than B" is provided, it is premised that cases in which "A is not greater than B" are taken into consideration.

According to the present disclosure, it is possible to reduce degradation in transfer capability due to irradiation.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-075416, filed Apr. 30, 2025, which is hereby incorporated by reference herein in its entirety.

What is claimed is:

1. A radiation detector comprising:
a semiconductor substrate having a surface;
a photodiode configured to convert radiation into at least one electric charge and accumulate at least one signal charge;
a transfer transistor configured to transfer the at least one signal charge accumulated by the photodiode;
a floating diffusion layer configured to convert the at least one signal charge into a voltage;
a reset transistor configured to reset the floating diffusion layer to a predetermined voltage; and
an amplification transistor configured to output an electrical signal based on a voltage of the floating diffusion layer,
wherein the transfer transistor, the reset transistor, and the amplification transistor each include a gate and a gate insulating film, which is provided between the gate and the surface, and
wherein the gate insulating film of the transfer transistor is thinner than the gate insulating film of at least one of the reset transistor and the amplification transistor.

2. The radiation detector according to claim 1, wherein the gate insulating film of the transfer transistor is thinner than the gate insulating film of the reset transistor.

3. The radiation detector according to claim 1, further comprising an insulating material,
wherein the insulating material isolates an active region in which the transfer transistor is provided from an active region in which the reset transistor is provided.

4. The radiation detector according to claim 1, further comprising:
a first pixel; and
a second pixel,
wherein the first pixel and the second pixel each include the photodiode and the transfer transistor, adjacent to each other, and
wherein at least one of the reset transistor and the amplification transistor is provided in a region between an active region in which the transfer transistor of the first pixel is provided and an active region in which the transfer transistor of the second pixel is provided.

5. The radiation detector according to claim 4,
wherein the first pixel and the second pixel each include a first region in which the transfer transistor is provided and a second region in which the reset transistor and the amplification transistor are provided,
wherein the second region extends over the first pixel and the second pixel, and
wherein the second region is provided between the first region of the first pixel and the first region of the second pixel.

6. The radiation detector according to claim 4, wherein a wiring length from the floating diffusion layer included in the first pixel to the gate of the amplification transistor is substantially equal to a wiring length from the floating diffusion layer included in the second pixel to the gate of the amplification transistor.

7. The radiation detector according to claim 1, further comprising a plurality of pixels,
wherein adjacent pixels of the plurality of pixels that each include the photodiode and the transfer transistor share the floating diffusion layer.

8. The radiation detector according to claim 1, further comprising:
a gate capacitor; and
a capacitance change transistor configured to change a connection state between the gate capacitor and the floating diffusion layer,
wherein a gate insulating film of the gate capacitor is thinner than the gate insulating film of the at least one of the reset transistor and the amplification transistor.

9. The radiation detector according to claim 1, further comprising:
a memory configured to hold the at least one signal charge accumulated by the photodiode; and
a memory transfer transistor configured to transfer the at least one signal charge from the photodiode to the memory,
wherein the transfer transistor transfers the at least one signal charge from the memory to the floating diffusion layer, and
wherein a gate insulating film of the memory transfer transistor is thinner than the gate insulating film of the at least one of the reset transistor and the amplification transistor.

10. The radiation detector according to claim 1, further comprising a first pixel, a second pixel, a third pixel, and a fourth pixel each including the photodiode and the transfer transistor,
wherein the first pixel and the second pixel are adjacent to each other in a first direction in a planar view,
wherein the third pixel and the fourth pixel are adjacent to each other in the first direction in the planar view,
wherein the first pixel and the third pixel are adjacent to each other in a second direction different from the first direction in the planar view,
wherein the second pixel and the fourth pixel are adjacent to each other in the second direction in the planar view,
wherein the first pixel, the second pixel, the third pixel, and the fourth pixel each include a first region in which the transfer transistor is provided and a second region in which the reset transistor and the amplification transistor are provided, and
wherein the second region extends over the first pixel, the second pixel, the third pixel, and the fourth pixel and is surrounded by the first regions of the first pixel, the second pixel, the third pixel, and the fourth pixel.

11. The radiation detector according to claim 1, further comprising either a signal processing circuit or a drive circuit,
wherein the signal processing circuit is configured to output signals generated by pixels provided on the semiconductor substrate to an outside,
wherein the drive circuit is configured to drive the pixels and the signal processing circuit, and
wherein the gate insulating film of the transfer transistor is substantially equal in thickness to a gate insulating film of at least one transistor included in the signal processing circuit or the drive circuit.

12. The radiation detector according to claim 1, wherein a thickness of the gate insulating film of the transfer transistor is 15 Å or more and 80 Å or less.

13. The radiation detector according to claim 1,
wherein the photodiode is configured to convert at least one of an electron beams, a gamma ray, and an X-ray into the at least one electric charge, and
wherein the electrical signal output by the amplification transistor is based on an amount of radiation of at least one of the electron beams, the gamma ray, and the X-ray.

14. The radiation detector according to claim 1,
wherein, in response to exposing the radiation detector to at least one of an electron beam, a gamma ray, and an X-ray, the photodiode converts the radiation into the at least one electric charge,
wherein the radiation includes visible light, and
wherein the amplification transistor outputs the electrical signal based on an amount of radiation of the radiation including the visible light.

15. A method of manufacturing a radiation detector, the method comprising:
preparing a semiconductor substrate having a surface;
forming a photodiode configured to convert radiation into at least one electric charge in the semiconductor substrate;
forming a gate insulating film on the surface; and
forming a gate of a transfer transistor, a gate of a reset transistor, and a gate of an amplification transistor on the gate insulating film,
wherein a gate insulating film of the transfer transistor is thinner than a gate insulating film of at least one of the reset transistor and the amplification transistor.

16. The radiation detector manufacturing method according to claim 15,
wherein forming of the gate insulating film includes performing a first thermal oxidation and a second thermal oxidation,
wherein in each of the first thermal oxidation and the second thermal oxidation, an insulating film is formed on an active region in which the reset transistor and the amplification transistor are to be provided and an active region in which the transfer transistor is to be provided, and
wherein, between the first thermal oxidation and the second thermal oxidation, at least a part of an insulating film provided on the active region in which the transfer transistor is to be provided is selectively removed.

17. A detection system comprising:
a radiation source configured to irradiate an imaging target; and
a radiation detector according to claim 1.
